(19) United States
(12) Patent Application Publication
(10) Pub. No.: US 2026/0292986 A1
(43) Pub. Date: Sep. 24, 2026

(54) WIRING SUBSTRATE

(71) Applicant: IBIDEN CO., LTD., Gifu (JP)

(72) Inventor: Naoki AWANO, Gifu (JP)

(73) Assignee: IBIDEN CO., LTD., Gifu (JP)

(21) Appl. No.: 19/377,524

(22) Filed: Nov. 3, 2025

Related U.S. Application Data
(63) Continuation of application No. PCT/JP2024/020166, filed on Jun. 3, 2024.

(30) Foreign Application Priority Data
Jun. 5, 2023 (JP) 2023-092463

(51) Int. Cl. H05K 1/11

(52) U.S. Cl. CPC H05K 1/116; H05K 2201/096

(57) ABSTRACT

A wiring substrate includes a first conductive layer, an insulating layer covering the first conductive layer, a second conductive layer formed on the insulating layer, and a via conductor formed in the insulating layer such that the via conductor is penetrating through the insulating layer and connecting the first conductive layer and the second conductive layer. The first conductive layer is formed such that the first conductive layer includes a pad connected to the via conductor and a solid pattern having an opening surrounding the pad and that gaps are formed between a side surface of the pad and the insulating layer and/or between an inner side surface of the opening of the solid pattern and the insulating layer.

### CROSS-REFERENCE TO RELATED APPLICATIONS

The present application is a continuation of and claims the benefit of priority to International Application No. PCT/JP 2024/020166, filed Jun. 3, 2024, which is based upon and claims the benefit of priority to Japanese Application No. 2023-092463, filed Jun. 5, 2023. The entire contents of these applications are incorporated herein by reference.

### BACKGROUND OF THE INVENTION

### Field of the Invention

The present invention relates to a wiring substrate in which conductive layers are connected to each other by via conductors.

### Description of Background Art

Japanese Patent Application Laid-Open Publication No. 2017-11093 describes a wiring substrate. The entire contents of this publication are incorporated herein by reference.

### SUMMARY OF THE INVENTION

According to one aspect of the present invention, a wiring substrate includes a first conductive layer, an insulating layer covering the first conductive layer, a second conductive layer formed on the insulating layer, and a via conductor formed in the insulating layer such that the via conductor is penetrating through the insulating layer and connecting the first conductive layer and the second conductive layer. The first conductive layer is formed such that the first conductive layer includes a pad connected to the via conductor and a solid pattern having an opening surrounding the pad and that gaps are formed between a side surface of the pad and the insulating layer and/or between an inner side surface of the opening of the solid pattern and the insulating layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is cross-sectional side view of a wiring substrate according to an embodiment of the present invention;

FIG. 2 is a cross-sectional plan view near a via land;

FIG. 3 is a cross-sectional side view near a via land;

FIGS. 4A to 4C are cross-sectional side views illustrating a method for manufacturing a wiring substrate according to an embodiment of the present invention;

FIGS. 5A and 5B are cross-sectional side views illustrating a method for manufacturing a wiring substrate according to an embodiment of the present invention;

FIGS. 6A and 6B are cross-sectional side views illustrating a method for manufacturing a wiring substrate according to an embodiment of the present invention;

FIGS. 7A and 7B are cross-sectional side views illustrating a method for manufacturing a wiring substrate according to an embodiment of the present invention;

FIG. 8 is cross-sectional side view illustrating a method for manufacturing a wiring substrate according to an embodiment of the present invention; and

FIG. 9 is a cross-sectional side view of a wiring substrate of a modified example according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

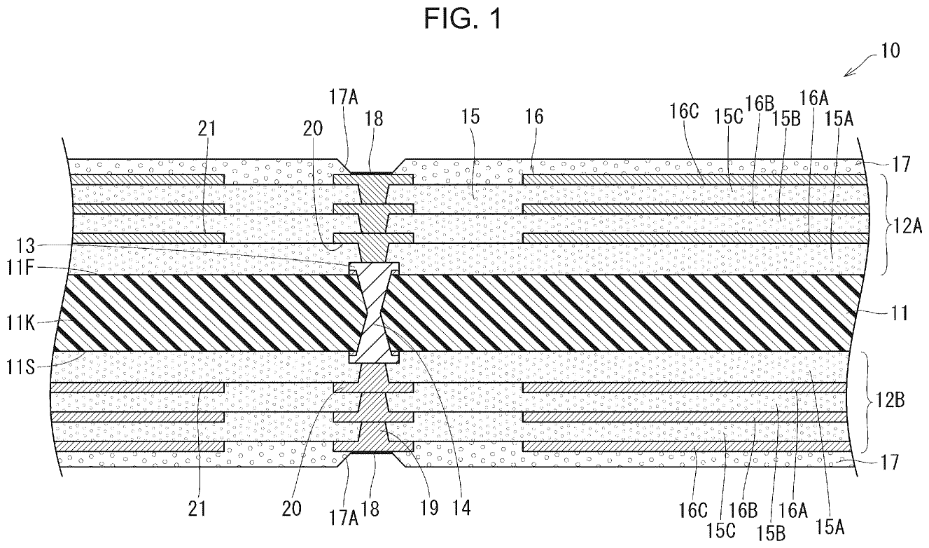

As illustrated in FIG. 1, a wiring substrate 10 according to an embodiment of the present invention includes a core substrate 11, and first and second build-up layers (12A, 12B) that are respectively laminated on front and back surfaces (a first surface (11F) and a second surface (11S)) of the core substrate 11.

The core substrate 11 includes an insulating layer (11K) and conductive layers 13 that are respectively laminated on front and back sides of the insulating layer (11K). The insulating layer (11K) has, for example, a structure in which multiple prepregs (B-stage resin sheets that are each obtained by impregnating a core material formed of fiber such as glass cloth with a resin) are laminated. Further, through-hole conductors 14 are formed in the insulating layer (11K).

The first and second build-up layers (12A, 12B) are each formed by alternately laminating insulating layers 15 and conductive layers 16. Specifically, in each of the first and second build-up layers (12A, 12B), from the core substrate 11 side, a first insulating layer (15A), a first conductive layer (16A), a second insulating layer (15B), a second conductive layer (16B), a third insulating layer (15C), and a third conductive layer (16C) are sequentially laminated. Each insulating layer 15 is, for example, an insulating film for build-up substrates (a film that does not contain a core material and is made of, for example, a thermosetting resin containing an inorganic filler), and each conductive layer 16 is mainly electrolytic plating. Further, in the first to third insulating layers (15A to 15C), via conductors 19 are formed that connect between the conductive layer 13 of the core substrate 11 and the first conductive layer (16A), between the first conductive layer (16A) and the second conductive layer (16B), and between the second conductive layer (16B) and the third conductive layer (16C). In the present embodiment, the first and second build-up layers (12A, 12B) have the same number of layers. However, it is also possible that the first and second build-up layers (12A, 12B) have different numbers of layers from each other.

A solder resist layer 17 having multiple openings (17A) corresponding to multiple pads 18 included in the third conductive layer (16C) is laminated on each of the first and second build-up layers (12A, 12B).

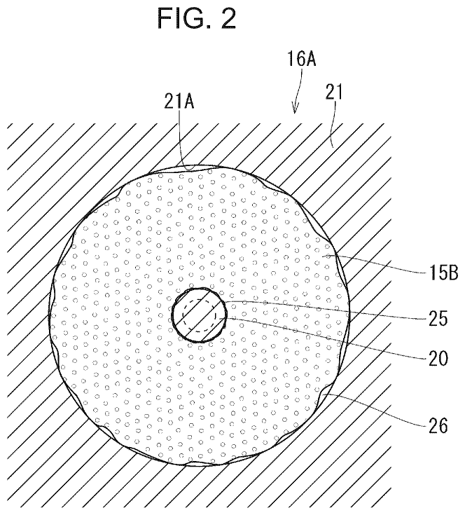

In the wiring substrate 10 of the present embodiment, the conductive layers 16 include via lands 20 (each also referred to as a “pad 20”), which are connected via the via conductors 19 and the through-hole conductors 14, and solid patterns 21 that each surround a via land 20. The via lands 20 of the conductive layers 16, the via conductors 19, and the through-hole conductors 14 are aligned in a vertical direction, and the pads 18 on the first build-up layer (12A) side and the pads 18 on the second build-up layer (12B) side are electrically connected. As illustrated in FIG. 2, each via land 20 has a circular planar shape, and a circular opening (21A) corresponding to the via land 20 is formed in a solid pattern 21. A diameter of the opening (21A) of the solid pattern 21 is 2 to 3 times a diameter of the via land 20, and a distance between a side surface of the via land 20 and an opening edge of the opening (21A) of the solid pattern 21 is about 300 to 700 μm.

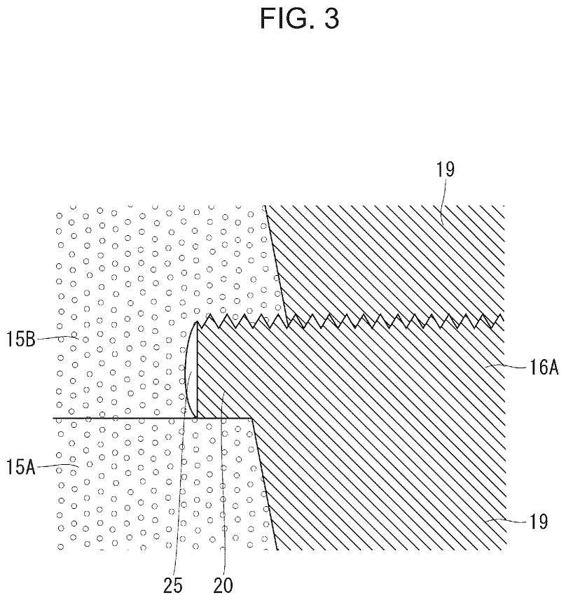

Here, as illustrated in FIG. 3, the side surface of the via land 20 has a smaller roughness than an upper surface of the via land 20. Then, while an insulating layer 15 is in close contact with an upper surface of the via land 20, it is partially peeled off from the side surface of the via land 20, and via land side gaps 25 are provided between the side surface of the via land 20 and the insulating layer 15.

Similarly, an inner side surface of the opening (21A) of the solid pattern 21 has a smaller roughness than an upper surface of the solid pattern 21. Then, while the insulating layer 15 is in close contact with the upper surface of the solid pattern 21, it is peeled off from the inner side surface of the opening (21A) of the solid pattern 21, and solid pattern side gaps 26 (see FIG. 2) are provided between the inner side surface of the opening (21A) of the solid pattern 21 and the insulating layer 15.

The via land side gaps 25 and the solid pattern side gaps 26 each have a length in a lateral direction of about 0.01 to 0.1 μm. In FIGS. 2 and 3, a via land 20 and a solid pattern 21 in the first conductive layer (16A) on the first build-up layer (12A) side are illustrated. However, via land side gaps 25 are also formed on a side surface of a via land 20 in the second conductive layer (16B) on the first build-up layer (12A) side. Further, via land side gaps 25 may be formed on side surfaces of all of the via lands 20, or may be formed only on side surfaces of some of the via lands 20. Further, gaps may be formed between a via land 20 of the third conductive layer (16C) and the solder resist layer 17.

As illustrated in FIG. 2, the via land side gaps 25 and the solid pattern side gaps 26 may be scattered, or may be formed between the insulating layer 15 and the entire side surface of the via land 20 and the entire inner side surface of the opening (21A) of the solid pattern 21. Further, the via land side gaps 25 and the solid pattern side gaps 26 may be scattered in the vertical direction.

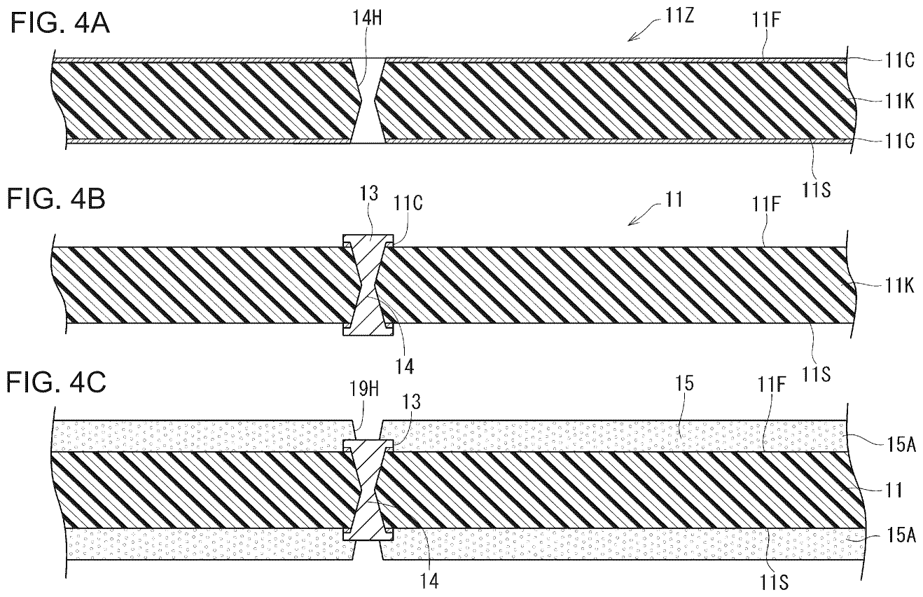

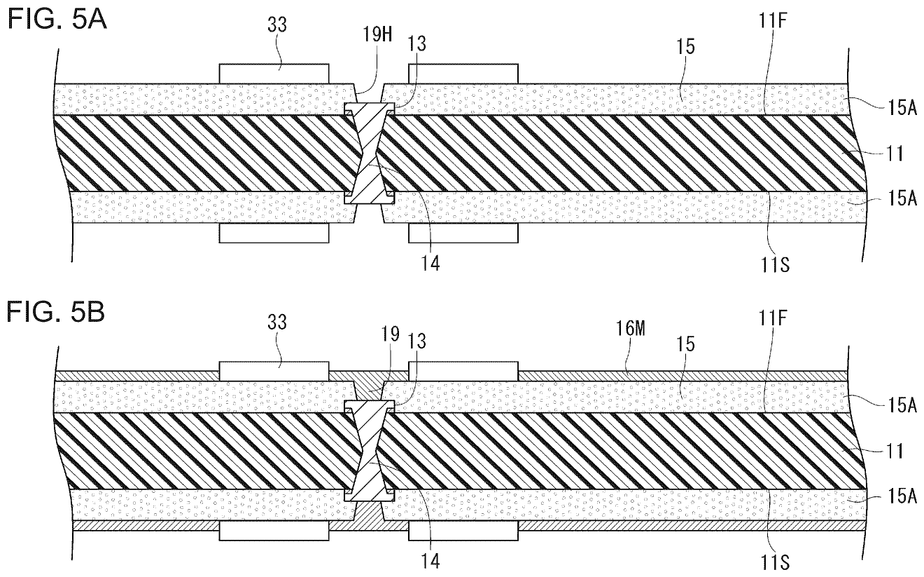

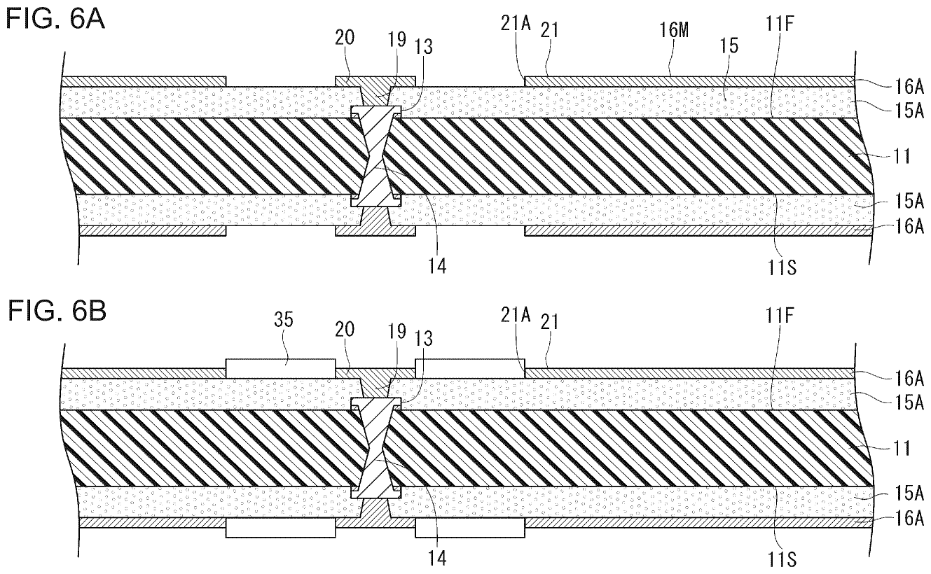

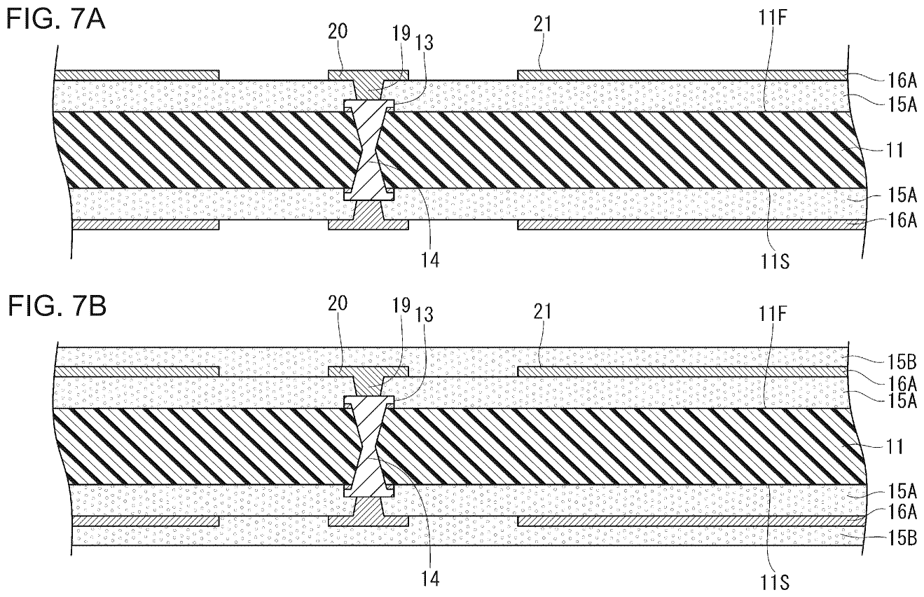

Next, a method for manufacturing the wiring substrate 10 is described.
(1) First, a copper-clad laminate (11Z) in which copper foils (11C) are laminated on both surfaces of the insulating layer (11K) is prepared, and as illustrated in FIG. 4A, through holes (14H) are formed by irradiating both surfaces of the copper-clad laminate (11Z) with laser.
(2) Using a subtractive method, the conductive layers 13 including the copper foils (11C) are respectively formed on the front and back surfaces of the insulating layer (11K), and the through-hole conductors 14 are formed on inner surfaces of the through holes (14H) (see FIG. 4B). As a result, the core substrate 11 is formed.
(3) Next, on the conductive layers 13 on the front and back surfaces of the core substrate 11, insulating films for build-up substrates are respectively laminated as insulating layers 15 and hot-pressed. In this case, portions of the conductive layers 13 where no patterns are formed are filled with the insulating films. As a result, the insulating layers 15 (first insulating layers (15A)) are respectively formed on the front and back surfaces of the core substrate 11.
(4) As illustrated in FIG. 4C, laser is irradiated to form tapered via holes (19H) penetrating the insulating layers 15, and insides of the via holes (19H) are cleaned (dry desmear treatment). Subsequently, an electroless plating treatment is performed, and an electroless plating film (not illustrated) is formed on the insulating layers 15 and on inner surfaces of the via holes (19H).
(5) As illustrated in FIG. 5A, a plating resist 33 having predetermined patterns is formed on the electroless plating film.
(6) As illustrated in FIG. 5B, an electrolytic plating treatment is performed, the via holes (19H) are filled with electrolytic plating to form the via conductors 19, and an electrolytic plating film (16M) is formed on portions of the electroless plating film (not illustrated) exposed from the plating resist 33 on the first surface (11F) side and the second surface (11S) side.
(7) As illustrated in FIG. 6A, the plating resist 33 is peeled off. Subsequently, the electroless plating film under the plating resist 33 is removed, and conductive layers 16 (the first conductive layers (16A)) are formed from the remaining electroless plating film and electrolytic plating film (16M). In the first conductive layers (16A), the via lands 20, which are connected to the via conductors 19 penetrating the first insulating layers (15A), and the solid patterns 21, which each surround a via land 20, are provided.
(8) Next, as illustrated in FIG. 6B, after a protective film 35 is formed between the via lands 20 and the solid patterns 21, a roughening treatment is performed on surfaces of the first conductive layers (16A). As a result, the side surfaces of the via lands 20 and the inner side surfaces of the openings (21A) of the solid patterns 21 are not roughened, while the upper surfaces of the via lands 20 and the upper surfaces of the solid patterns 21 are roughened, and roughness of the side surfaces of the via lands 20 and the inner side surfaces of the openings (21A) of the solid patterns 21 becomes smaller than roughness of the upper surfaces of the via lands 20 and the upper surfaces of the solid patterns 21.
(9) As illustrated in FIG. 7A, the protective film 35 is removed.
(10) As illustrated in FIG. 7B, insulating films for build-up substrates are respectively laminated as insulating layers 15 and hot-pressed. In this case, portions of the conductive layers 16 where no patterns are formed, including portions between the via lands 20 and the solid patterns 21, are filled with the insulating films. As a result, the insulating layers 15 (second insulating layers (15B)) are respectively formed on the first conductive layers (16A).

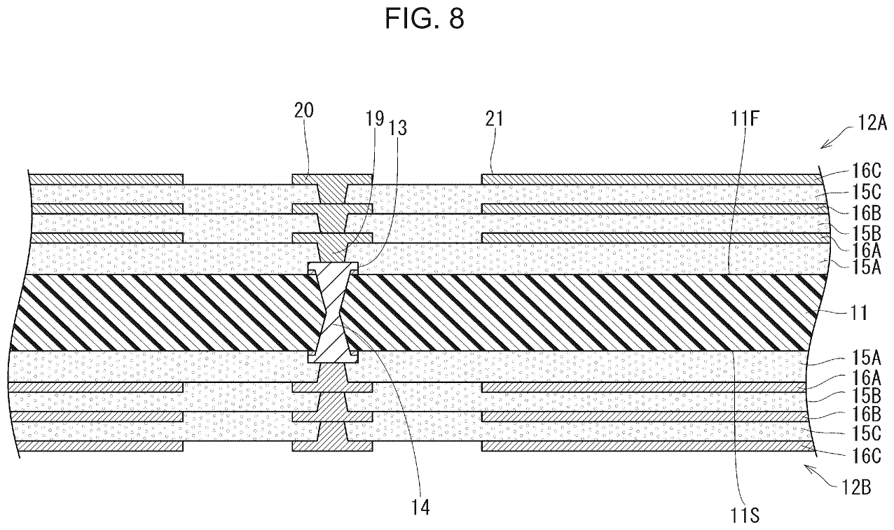

In this case, due to thermal shrinkage of the insulating films for build-up substrates, portions of the insulating layers 15 between the via lands 20 and the solid patterns 21 are partially peeled off from the side surfaces of the via lands 20 and the inner side surfaces of the openings (21A) of the solid patterns 21, which have relatively small roughness. As a result, the via land side gaps 25 and the solid pattern side gaps 26 are respectively formed between the side surfaces of the via lands 20 and the insulating layers 15, and between the inner side surfaces of the openings (21A) of the solid patterns 21 and the insulating layers 15.
(11) The same processes as (4) to (10) described above are repeated, and as illustrated in FIG. 8, the second conductive layers (16B), the third insulating layers (15C), and the third conductive layers (16C) are formed.
(12) On the third conductive layers (16C), the solder resist layers 17 are respectively laminated. Subsequently, the openings (17A) are formed at predetermined positions of the solder resist layers 17, for example, by laser processing or photolithography. Then, the pads 18 are formed on portions of the third conductive layers (16C) that are exposed from the openings (17A) of the solder resist layers 17.
(13) On the pads 18, a metal film is formed by sequentially laminating a nickel layer, a palladium layer, and a gold layer. As a result, the wiring substrate 10 illustrated in FIG. 1 is completed.

Next, operational effects of the wiring substrate 10 and the manufacturing method thereof are described. In the wiring substrate 10 of the present embodiment, the via lands 20 that are connected in the vertical direction via the via conductors 19 are each surrounded by a solid pattern 21. Here, it is thought that when a stray capacitance occurs between the side surfaces of the via lands 20 and the solid patterns 21, a high-frequency signal may be affected.

In contrast, in the wiring substrate 10 of the present embodiment, the via land side gaps 25 are provided between the side surfaces of the via lands 20 and the insulating layers 15, and presence of air having a low dielectric constant can reduce a generated stray capacitance. As a result, the influence on a high-frequency signal can also be reduced.

Moreover, since the solid pattern side gaps 26 are provided between the inner side surfaces of the openings (21A) of the solid patterns 21 and the insulating layers 15, a generated stray capacitance can be reduced even further.

Further, by protecting the side surfaces of the via lands 20 and the inner side surfaces of the openings (21A) of the solid patterns 21 at the stage of roughening the conductive layers 16, it is possible to selectively generate the via land side gaps 25 and the solid pattern side gaps 26 between the side surfaces when the insulating films serving as the insulating layers 15 are hot-pressed, and thus, occurrence of unnecessary gaps (for example, occurrence of gaps between the upper surfaces of the via lands 20 and the insulating layers 15) can be suppressed.

### Other Embodiments

In the above embodiment, the via land side gaps 25 are formed by reducing the roughness of the side surfaces of the via lands 20. However, for example, it is also possible that the via land side gaps 25 are formed by allowing a desmear solution for a desmear treatment in the via holes (19H) to penetrate. In this case, it is thought that the via land side gaps 25 are scattered on the upper surfaces of the via lands 20 and on the side surfaces of the via lands 20.

In the state illustrated in FIG. 5B in which the plating resist 33 is formed, roughening of the upper surface of the electrolytic plating film (16M) may be performed. In this case as well, a difference in roughness can be achieved between the side surface and the upper surface of each via land 20. In this case, since the process of forming the protective film 35 is unnecessary, the manufacturing process can be simplified. However, since a treatment for removing the electroless plating film (for example, quick etching) is performed after roughening, roughness during roughening is set with the expectation that the roughness of the upper surface of each via land 20 will be reduced.

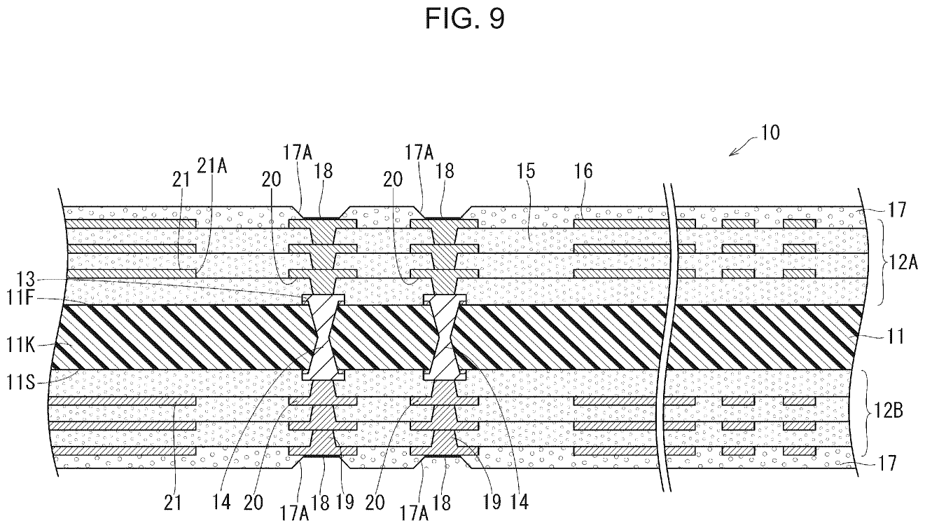

As illustrated in FIG. 9, multiple via lands 20 may be formed in an opening (21A) of a solid pattern 21, or there may be positions in the conductive layers 16 where multiple wirings are formed in parallel. In this case, it is thought that, when a distance between via lands 20 or between wirings is smaller than a distance between a side surface of a via land 20 and an inner side surface of an opening (21A) of a solid pattern 21, a volume of resin of an insulating layer 15 formed between via lands 20 and between wirings is small, and peeling due to thermal shrinkage is unlikely to occur.

The wiring substrate 10 may have a coreless structure.

It is also possible that only the via land side gaps 25 or only the solid pattern side gaps 26 are provided.

In a wiring substrate, a land of a via conductor connecting conductive layers may be surrounded by a solid pattern (see, for example, Japanese Patent Application Laid-Open Publication No. 2017-11093 (FIG. 1)), and a stray capacitance occurs between a side of the land and a side surface of the solid pattern.

A wiring substrate according to an embodiment of the present invention includes: a first conductive layer; an insulating layer that covers the first conductive layer; a second conductive layer that is formed on the insulating layer; and a via conductor that penetrates the insulating layer and connects the first conductive layer and the second conductive layer. A pad connected to the via conductor and a solid pattern having an opening surrounding the pad are provided in the first conductive layer. Gaps are provided between a side surface of the pad and the insulating layer or between an inner side surface of the opening of the solid pattern and the insulating layer.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a first conductive layer;
an insulating layer covering the first conductive layer;
a second conductive layer formed on the insulating layer; and
a via conductor formed in the insulating layer such that the via conductor is penetrating through the insulating layer and connecting the first conductive layer and the second conductive layer,
wherein the first conductive layer is formed such that the first conductive layer includes a pad connected to the via conductor and a solid pattern having an opening surrounding the pad and that a plurality of gaps is formed between a side surface of the pad and the insulating layer and/or between an inner side surface of the opening of the solid pattern and the insulating layer.

2. The wiring substrate according to claim 1, wherein the plurality of gaps is formed between the side surface of the pad and the insulating layer and between the inner side surface of the opening of the solid pattern and the insulating layer.

3. The wiring substrate according to claim 1, wherein the first conductive layer is formed such that roughness of the side surface of the pad is smaller than roughness of an upper surface of the pad.

4. The wiring substrate according to claim 1, wherein the first conductive layer is formed such that the gaps are formed between the side surface of the pad and the insulating layer and/or between the inner side surface of the opening of the solid pattern and the insulating layer at scattered positions.

5. The wiring substrate according to claim 1, wherein the first conductive layer is formed such that the gaps have a maximum width in a range of 0.01 to 0.1 μm.

6. The wiring substrate according to claim 1, wherein the first conductive layer is formed such that a distance between the side surface of the pad and the inner side surface of the opening of the solid pattern is formed in a range of 300 to 700 μm.

7. The wiring substrate according to claim 1, wherein the first conductive layer is formed such that a diameter of the opening of the solid pattern is formed in a range of 2 to 3 times a diameter of the pad.

8. The wiring substrate according to claim 2, wherein the first conductive layer is formed such that roughness of the side surface of the pad is smaller than roughness of an upper surface of the pad.

9. The wiring substrate according to claim 2, wherein the first conductive layer is formed such that the gaps are formed between the side surface of the pad and the insulating layer and/or between the inner side surface of the opening of the solid pattern and the insulating layer at scattered positions.

10. The wiring substrate according to claim 2, wherein the first conductive layer is formed such that the gaps have a maximum width in a range of 0.01 to 0.1 μm.

11. The wiring substrate according to claim 2, wherein the first conductive layer is formed such that a distance between the side surface of the pad and the inner side surface of the opening of the solid pattern is formed in a range of 300 to 700 μm.

12. The wiring substrate according to claim 2, wherein the first conductive layer is formed such that a diameter of the opening of the solid pattern is formed in a range of 2 to 3 times a diameter of the pad.

13. The wiring substrate according to claim 3, wherein the first conductive layer is formed such that the gaps are formed between the side surface of the pad and the insulating layer and/or between the inner side surface of the opening of the solid pattern and the insulating layer at scattered positions.

14. The wiring substrate according to claim 3, wherein the first conductive layer is formed such that the gaps have a maximum width in a range of 0.01 to 0.1 μm.

15. The wiring substrate according to claim 3, wherein the first conductive layer is formed such that a distance between the side surface of the pad and the inner side surface of the opening of the solid pattern is formed in a range of 300 to 700 μm.

16. The wiring substrate according to claim 3, wherein the first conductive layer is formed such that a diameter of the opening of the solid pattern is formed in a range of 2 to 3 times a diameter of the pad.

17. The wiring substrate according to claim 4, wherein the first conductive layer is formed such that the gaps have a maximum width in a range of 0.01 to 0.1 μm.

18. The wiring substrate according to claim 4, wherein the first conductive layer is formed such that a distance between the side surface of the pad and the inner side surface of the opening of the solid pattern is formed in a range of 300 to 700 μm.

19. The wiring substrate according to claim 4, wherein the first conductive layer is formed such that a diameter of the opening of the solid pattern is formed in a range of 2 to 3 times a diameter of the pad.

20. The wiring substrate according to claim 5, wherein the first conductive layer is formed such that a distance between the side surface of the pad and the inner side surface of the opening of the solid pattern is formed in a range of 300 to 700 μm.
